(19) United States
(12) Patent Application Publication
(10) Pub. No.: US 2025/0348647 A1
(43) Pub. Date: Nov. 13, 2025

(54) AUTOMATED FLOORPLAN ASSISTANCE FOR LARGE BLOCKS, SOFT BLOCKS AND PORTS

(71) Applicant: International Business Machines Corporation, Armonk, NY (US)

(72) Inventors: George Antony, Cochin (IN); Naiju Karim Abdul, Babusapalaya (IN)

(21) Appl. No.: 18/657,889

(22) Filed: May 8, 2024

(51) Int. Cl. G06F 30/392; G06F 30/394

(52) U.S. Cl. CPC G06F 30/392; G06F 30/394

(57) ABSTRACT

A computer-implemented method for automated floorplan assistance is provided. The computer-implemented method includes automating simultaneous placements of large blocks, soft blocks and ports into a grid, grouping the large blocks, the soft blocks and the ports into nodes, executing a learning flow for both coarse movements and fine movements of the nodes relative to the grid to iteratively improve a floorplan of the grid by assigning rewards associated with placement tool steering in accordance with learned attractions of the nodes toward certain areas of the grid, executing a dynamic grid size determination based on sizes of the nodes to enable handling of multiple nodes of differing sizes together and generating an output comprising a grid size in accordance with the dynamic grid size determination and node assignments for each node at grid locations associated with greatest rewards.

### BACKGROUND

The present invention generally relates to computing systems. More specifically, the present invention relates to automated floorplan assistance for large blocks, soft blocks and ports with machine learning (ML) techniques in semiconductor electronic design automation (EDA) for computing systems.

In very large-scale integration (VLSI) digital design, fabricated devices conventionally include millions of transistors implementing hundreds of storage devices, functional logic circuits and the like. EDA involves the use of software tools for designing electronic systems such as integrated circuits (ICs) and printed circuit boards (PCBs). The designs are often segmented or partitioned into sub-blocks (such as cores, units, macros, sub-hierarchies, and the like) to make the design process more manageable.

As technology shrinks to smaller devices while design sizes keep growing, existing options for automated floorplan assistance tend to be inefficient due to various reasons. These include accuracies of optimization environments varying when going through physical synthesis flows as well as a need to optimize multiple objectives, such as improving timing, decreasing area and/or power, reducing congestion and fixing electrical violations.

### SUMMARY

A computer-implemented method for automated floorplan assistance is provided. The computer-implemented method includes automating simultaneous placements of large blocks, soft blocks and ports into a grid, grouping the large blocks, the soft blocks and the ports into nodes, executing a learning flow for both coarse movements and fine movements of the nodes relative to the grid to iteratively improve a floorplan of the grid by assigning rewards associated with placement tool steering in accordance with learned attractions of the nodes toward certain areas of the grid, executing a dynamic grid size determination based on sizes of the nodes to enable handling of multiple nodes of differing sizes together and generating an output comprising a grid size in accordance with the dynamic grid size determination and node assignments for each node at grid locations associated with greatest rewards.

According to an aspect of the disclosure, a computer program product for automated floorplan assistance is provided. The computer program product includes one or more computer readable storage media having computer readable program code collectively stored on the one or more computer readable storage media. The computer readable program code is executed by a processor of a computer system to cause the computer system to perform a method including automating simultaneous placements of large blocks, soft blocks and ports into a grid, grouping the large blocks, the soft blocks and the ports into nodes, executing a learning flow for both coarse movements and fine movements of the nodes relative to the grid to iteratively improve a floorplan of the grid by assigning rewards associated with placement tool steering in accordance with learned attractions of the nodes toward certain areas of the grid, executing a dynamic grid size determination based on sizes of the nodes to enable handling of multiple nodes of differing sizes together and generating an output comprising a grid size in accordance with the dynamic grid size determination and node assignments for each node at grid locations associated with greatest rewards.

According to another aspect of the disclosure, a computing system is provided and includes a processor, a memory coupled to the processor and one or more computer readable storage media coupled to the processor. The one or more computer readable storage media collectively contain instructions that are executed by the processor via the memory to implement a method for automated floorplan assistance. The method for automated floorplan assistance includes automating simultaneous placements of large blocks, soft blocks and ports into a grid, grouping the large blocks, the soft blocks and the ports into nodes, executing a learning flow for both coarse movements and fine movements of the nodes relative to the grid to iteratively improve a floorplan of the grid by assigning rewards associated with placement tool steering in accordance with learned attractions of the nodes toward certain areas of the grid, executing a dynamic grid size determination based on sizes of the nodes to enable handling of multiple nodes of differing sizes together and generating an output comprising a grid size in accordance with the dynamic grid size determination and node assignments for each node at grid locations associated with greatest rewards.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a schematic diagram of a computing environment for automated floorplan assistance in accordance with one or more embodiments;

FIG. 2 is a block diagram of components of a machine learning training and inference system in accordance with one or more embodiments;

FIG. 3 is a flow diagram illustrating a computer-implemented method for automated floorplan assistance in accordance with one or more embodiments;

FIG. 4 is a schematic illustration of an initial placement of large blocks, soft blocks and ports in a grid in accordance with one or more embodiments;

FIG. 5 is a schematic illustration of groupings of large blocks, soft blocks and ports in a grid in accordance with one or more embodiments;

FIG. 6 is a flow diagram illustrating a learning flow of the automated floorplan assistance of the computer-implemented method of FIG. 3 in accordance with one or more embodiments;

FIG. 7 is a graphical depiction of tables generating during a coarse operational stage of the learning flow of FIG. 6 in accordance with one or more embodiments;

FIG. 8 is a graphical illustration of a reward generation for port positioning in a grid in accordance with one or more embodiments;

FIG. 9A is a flow diagram illustrating a supervised machine learning operation to predict rewards for a given floorplan in accordance with one or more embodiments; and

FIG. 9B is a graphical depiction of fine movements during the learning flow of FIG. 6 in accordance with one or more embodiments.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two- or three-digit reference numbers. With minor exceptions, the leftmost digit(s) of each reference number correspond to the figure in which its element is first illustrated.

### DETAILED DESCRIPTION

According to an aspect of the disclosure, a computer-implemented method for automated floorplan assistance is provided. The computer-implemented method includes automating simultaneous placements of large blocks, soft blocks and ports into a grid, grouping the large blocks, the soft blocks and the ports into nodes, executing a learning flow for both coarse movements and fine movements of the nodes relative to the grid to iteratively improve a floorplan of the grid by assigning rewards associated with placement tool steering in accordance with learned attractions of the nodes toward certain areas of the grid, executing a dynamic grid size determination based on sizes of the nodes to enable handling of multiple nodes of differing sizes together and generating an output comprising a grid size in accordance with the dynamic grid size determination and node assignments for each node at grid locations associated with greatest rewards. This provides for improves design closure with a better correct-by-construction floorplan.

The automating of the simultaneous placements includes netlist definitions with connectivity information. This provides for an abstract definition of an initial floorplan and requirements thereof.

The grouping of the large blocks, the soft blocks and the ports into the nodes is based on at least connectivity information and user preferences. This provides for a further abstract definition of an initial floorplan and requirements thereof.

The executing of the learning flow includes a learning phase for the coarse movements and a learning phase for the fine movements and the coarse movements include assigning nodes to grids and the fine movements comprise moving nodes to neighboring grids. The dual learning phases allow for the fine movement learning flow to use knowledge gleaned from the coarse movement learning flow.

The rewards are based on overall/local congestion, wirelengths, timing and power requirements. These rewards encourage formation of an optimal floorplan.

The dynamic grid size determination includes expanding a node assignment to a grid to a neighboring grid in an event a size of the node exceeds a size of the grid. This allows for a grid to be effectively increased in size to provide room for an optimal floorplan.

The computer-implemented method further includes assigning a reward for each node at a given grid based on a weighted sum of global and local considerations with higher weights given to wirelengths and congestion. This increases a tendency for the optimized floorplan to be identified and configured.

According to an aspect of the disclosure, a computer program product for automated floorplan assistance is provided. The computer program product includes one or more computer readable storage media having computer readable program code collectively stored on the one or more computer readable storage media. The computer readable program code is executed by a processor of a computer system to cause the computer system to perform a method including automating simultaneous placements of large blocks, soft blocks and ports into a grid, grouping the large blocks, the soft blocks and the ports into nodes, executing a learning flow for both coarse movements and fine movements of the nodes relative to the grid to iteratively improve a floorplan of the grid by assigning rewards associated with placement tool steering in accordance with learned attractions of the nodes toward certain areas of the grid, executing a dynamic grid size determination based on sizes of the nodes to enable handling of multiple nodes of differing sizes together and generating an output comprising a grid size in accordance with the dynamic grid size determination and node assignments for each node at grid locations associated with greatest rewards.

The automating of the simultaneous placements includes netlist definitions with connectivity information. This provides for an abstract definition of an initial floorplan and requirements thereof.

The grouping of the large blocks, the soft blocks and the ports into the nodes is based on at least connectivity information and user preferences. This provides for a further abstract definition of an initial floorplan and requirements thereof.

The executing of the learning flow includes a learning phase for the coarse movements and a learning phase for the fine movements and the coarse movements include assigning nodes to grids and the fine movements comprise moving nodes to neighboring grids. The dual learning phases allow for the fine movement learning flow to use knowledge gleaned from the coarse movement learning flow.

The rewards are based on overall/local congestion, wirelengths, timing and power requirements. These rewards encourage formation of an optimal floorplan.

The dynamic grid size determination includes expanding a node assignment to a grid to a neighboring grid in an event a size of the node exceeds a size of the grid. This allows for a grid to be effectively increased in size to provide room for an optimal floorplan.

The method further includes assigning a reward for each node at a given grid based on a weighted sum of global and local considerations with higher weights given to wirelengths and congestion. This increases a tendency for the optimized floorplan to be identified and configured.

According to another aspect of the disclosure, a computing system is provided and includes a processor, a memory coupled to the processor and one or more computer readable storage media coupled to the processor. The one or more computer readable storage media collectively contain instructions that are executed by the processor via the memory to implement a method for automated floorplan assistance. The method for automated floorplan assistance includes automating simultaneous placements of large blocks, soft blocks and ports into a grid, grouping the large blocks, the soft blocks and the ports into nodes, executing a learning flow for both coarse movements and fine movements of the nodes relative to the grid to iteratively improve a floorplan of the grid by assigning rewards associated with placement tool steering in accordance with learned attractions of the nodes toward certain areas of the grid, executing a dynamic grid size determination based on sizes of the nodes to enable handling of multiple nodes of differing sizes together and generating an output comprising a grid size in accordance with the dynamic grid size determination and node assignments for each node at grid locations associated with greatest rewards.

The automating of the simultaneous placements includes netlist definitions with connectivity information. This provides for an abstract definition of an initial floorplan and requirements thereof.

The grouping of the large blocks, the soft blocks and the ports into the nodes is based on at least connectivity information and user preferences. This provides for a further abstract definition of an initial floorplan and requirements thereof.

The executing of the learning flow includes a learning phase for the coarse movements and a learning phase for the fine movements and the coarse movements include assigning nodes to grids and the fine movements comprise moving nodes to neighboring grids. The dual learning phases allow for the fine movement learning flow to use knowledge gleaned from the coarse movement learning flow.

The rewards are based on overall/local congestion, wirelengths, timing and power requirements. These rewards encourage formation of an optimal floorplan.

The dynamic grid size determination includes expanding a node assignment to a grid to a neighboring grid in an event a size of the node exceeds a size of the grid. This allows for a grid to be effectively increased in size to provide room for an optimal floorplan.

The method for automated floorplan assistance further includes assigning a reward for each node at a given grid based on a weighted sum of global and local considerations with higher weights given to wirelengths and congestion. This increases a tendency for the optimized floorplan to be identified and configured.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

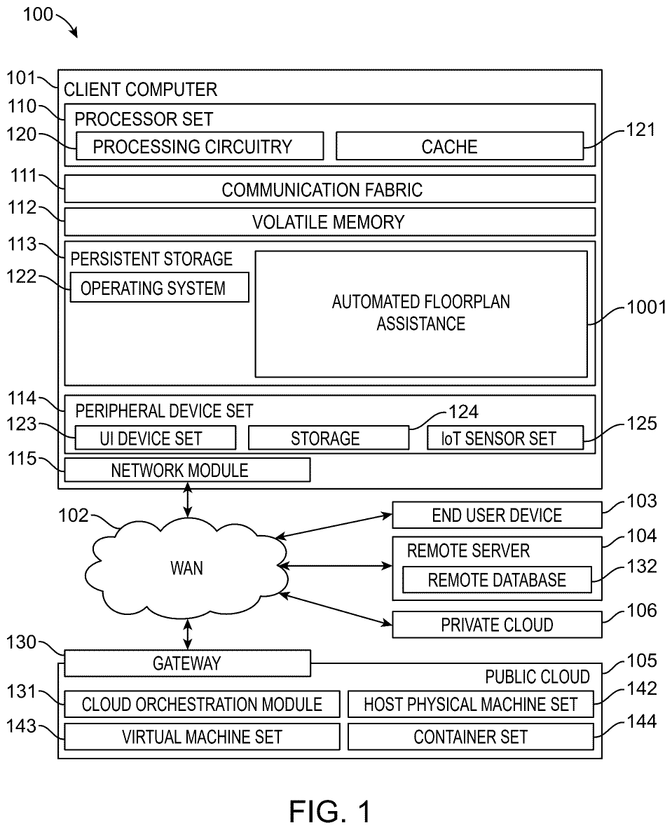

With reference to FIG. 1, a computer or computing device 100 that implements a computer-implemented method for automated floorplan assistance. The computer or computing device 100 of FIG. 1 contains an example of an environment for the execution of at least some of the computer code involved in performing the inventive methods, such as the block 1001 of the computer-implemented method for automated floorplan assistance. In addition to the computer-implemented method for automated floorplan assistance of block 1001, the computer or computing device 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and the computer-implemented method of block 1001, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

The computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of the computer-implemented method, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

The processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In the computer-implemented method, at least some of the instructions for performing the inventive methods may be stored in the block 1001 of the computer-implemented method in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in the block 1001 of the computer-implemented method typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Turning now to an overview of technologies that are more specifically relevant to aspects of the invention, large block (IP) floorplan methods typically include manual approaches based on IP data flow analyses, analytical tool and certain ML techniques. For example, a designer might pre-place IPs prior to placement driven synthesis (PDS), certain tools within PDS may automatically place Ips based on connectivity and a designer's rules of thumb may dictate that a tool is used as a guide to get seed locations for Ips, iteration over IP placements to improve congestion, movement of IPs to boundaries and leaving center regions for critical logic, locking down IPs progressively and placement of IPs densely and in pairs. In other instances, a port floorplan method involves integrator placement of ports communications with blocks at unit levels and/or interior pinning in PDS that has a capability to place ports based on where logic connections are placed. In a soft block floorplan method, a designer manually picks locations to place logic hierarchies based on data flow analyses.

In a conventional method, a netlist graph of macros and standard cells is placed onto a chip canvas such that power, performance and area (PPA) are optimized, while adhering to constraints on placement density and routing congestion but does not consider aspects of ports in optimization and does not offer coarse and fine movement approaches. This conventional method also tries to find absolute legal locations using masks rather than aiding a floor planner with rewards being calculated as weighted sums of proxy wirelengths and congestion. In another conventional method, a floorplan is learned through acquisitions of effective local search heuristics. In this case, the possibility of acquiring local search heuristics through massive search experiments (a local search algorithm starts off with an initial solution and then continually tries to find better solutions by searching neighborhoods like simulated annealing) is explored but does not consider soft blocks and ports in optimization and lacks coarse and fine movement approaches. In yet another conventional method, macro placement is evaluated through a prediction methodology after macro placement, rather than after cell placement and global routing but does not find or aid a placement solution.

In general, conventional methods tend not to consider soft block and port placement in optimization and lack coarse and fine movement approaches.?

The above-described aspects of the invention address the shortcomings of the prior art by providing a computer-implemented method for automated floorplan assistance that improves design closure with better correct-by-construction floorplans. The computer-implemented method aids automated large/soft bock and port placement tools to model timing/power/congestion constraints through attractions generated based on prior floorplan synthesis runs guided by ML learning phases. The computer-implemented method uses local costs like congestion/timing/power on each large/soft/port to assign rewards along with overall global costs during learning phases and evaluates fine moves for large block/soft block/ports (immediate left/right/top/bottom) based on a model trained with data from prior floorplan runs. This results in faster convergence on good floorplans which otherwise take weeks to finalize as well as improved designs with better wirelength, timing, congestion and reduced power requirements.

The computer-implemented method for automated floorplan assistance includes automating simultaneous placements of large blocks, soft blocks and ports, grouping the large blocks, the soft blocks and the ports into nodes, executing a learning flow for both coarse movements and fine movements of the nodes to iteratively improve a floorplan based on rewards associated with placement tool steering with learned attractions, executing a dynamic grid size determination based on sizes of the nodes to enable handling of multiple nodes of differing sizes together, assigning the rewards to the nodes and generating an output defining placements of the large blocks, the soft blocks and the ports.

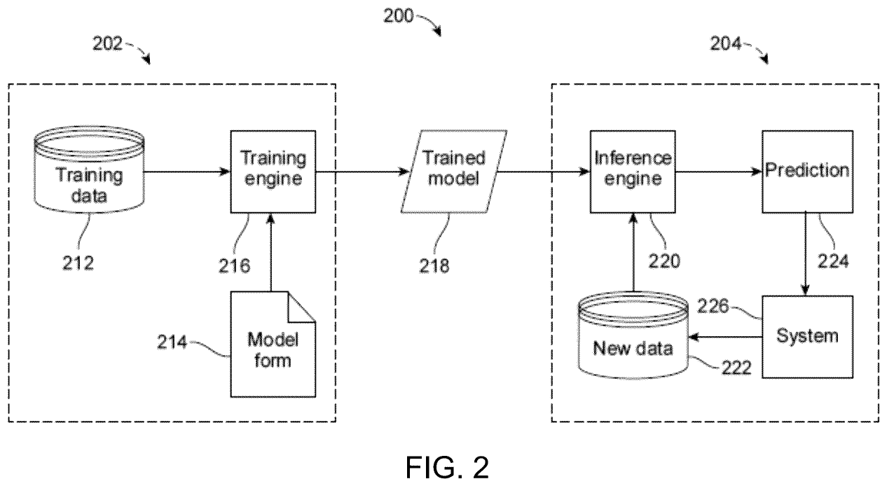

Turning now to a more detailed description of aspects of the present invention, FIG. 2 depicts a block diagram of components of a machine learning training and inference system 200. The machine learning training and inference system 200, in accordance with one or more embodiments of the invention, can utilize machine learning techniques to perform tasks, such as a computer-implemented method for automated floorplan assistance. Embodiments of the invention utilize AI, which includes a variety of so-called machine learning technologies. The phrase “machine learning” broadly describes a function of electronic systems that learn from data. A machine learning system, engine, or module can include a trainable machine learning algorithm that can be trained, such as in an external cloud environment, to learn functional relationships between inputs and outputs, and the resulting model (sometimes referred to as a “trained neural network,” “trained model,” and/or “trained machine learning model”) can be used for managing information during a web conference, for example. In one or more embodiments of the invention, machine learning functionality can be implemented using an artificial neural network (ANN) having the capability to be trained to perform a function. In machine learning and cognitive science, ANNs are a family of statistical learning models inspired by the biological neural networks of animals, and in particular the brain. ANNs can be used to estimate or approximate systems and functions that depend on a large number of inputs. Convolutional neural networks (CNN) are a class of deep, feed-forward ANNs that are particularly useful at tasks such as, but not limited to analyzing visual imagery and natural language processing (NLP). Recurrent neural networks (RNN) are another class of deep, feed-forward ANNs and are particularly useful at tasks such as, but not limited to, unsegmented connected handwriting recognition and speech recognition. Other types of neural networks are also known and can be used in accordance with one or more embodiments of the invention described herein.

ANNs can be embodied as so-called “neuromorphic” systems of interconnected processor elements that act as simulated “neurons” and exchange “messages” between each other in the form of electronic signals. Similar to the so-called “plasticity” of synaptic neurotransmitter connections that carry messages between biological neurons, the connections in ANNs that carry electronic messages between simulated neurons are provided with numeric weights that correspond to the strength or weakness of a given connection. The weights can be adjusted and tuned based on experience, making ANNs adaptive to inputs and capable of learning. For example, an ANN for handwriting recognition is defined by a set of input neurons that can be activated by the pixels of an input image. After being weighted and transformed by a function determined by the network's designer, the activation of these input neurons are then passed to other downstream neurons, which are often referred to as “hidden” neurons. This process is repeated until an output neuron is activated. The activated output neuron determines which character was input. It should be appreciated that these same techniques can be applied in the case of localizing a target object referred by a compositional expression from an image set with similar visual elements as described herein.

The machine learning training and inference system 200 performs training 202 and inference 204. During training 202, a training engine 216 trains a model (e.g., the trained model 218) to perform a task. Inference 204 is the process of implementing the trained model 218 to perform the task in the context of a larger system (e.g., a system 226).

The training 202 begins with training data 212, which can be structured or unstructured data. The training engine 216 receives the training data 212 and a model form 214. The model form 214 represents a base model that is untrained. The model form 214 can have preset weights and biases, which can be adjusted during training. It should be appreciated that the model form 214 can be selected from many different model forms depending on the task to be performed. For example, where the training 202 is to train a model to perform image classification, the model form 214 can be a model form of a CNN (convolutional neural network). The training 202 can be supervised learning, semi-supervised learning, unsupervised learning, reinforcement learning, and/or the like, including combinations and/or multiples thereof. For example, supervised learning can be used to train a machine learning model to classify an object of interest in an image. To do this, the training data 212 includes labeled images, including images of the object of interest with associated labels (ground truth) and other images that do not include the object of interest with associated labels. In this example, the training engine 216 takes as input a training image from the training data 212, makes a prediction for classifying the image, and compares the prediction to the known label. The training engine 216 then adjusts weights and/or biases of the model based on results of the comparison, such as by using backpropagation. The training 202 can be performed multiple times (referred to as “epochs”) until a suitable model is trained (e.g., the trained model 218).

Once trained, the trained model 218 can be used to perform inference 204 to perform a task. The inference engine 220 applies the trained model 218 to new data 222 (e.g., real-world, non-training data). For example, if the trained model 218 is trained to classify images of a particular object, such as a chair, the new data 222 can be an image of a chair that was not part of the training data 212. In this way, the new data 222 represents data to which the model 218 has not been exposed. The inference engine 220 makes a prediction 224 (e.g., a classification of an object in an image of the new data 222) and passes the prediction 224 to the system 226. The system 226 can, based on the prediction 224, taken an action, perform an operation, perform an analysis, and/or the like, including combinations and/or multiples thereof. In some embodiments of the invention, the system 226 can add to and/or modify the new data 222 based on the prediction 224.

In accordance with one or more embodiments of the invention, the predictions 224 generated by the inference engine 220 are periodically monitored and verified to ensure that the inference engine 220 is operating as expected. Based on the verification, additional training 202 can occur using the trained model 218 as the starting point. The additional training 202 can include all or a subset of the original training data 212 and/or new training data 212. In accordance with one or more embodiments of the invention, the training 202 includes updating the trained model 218 to account for changes in expected input data.

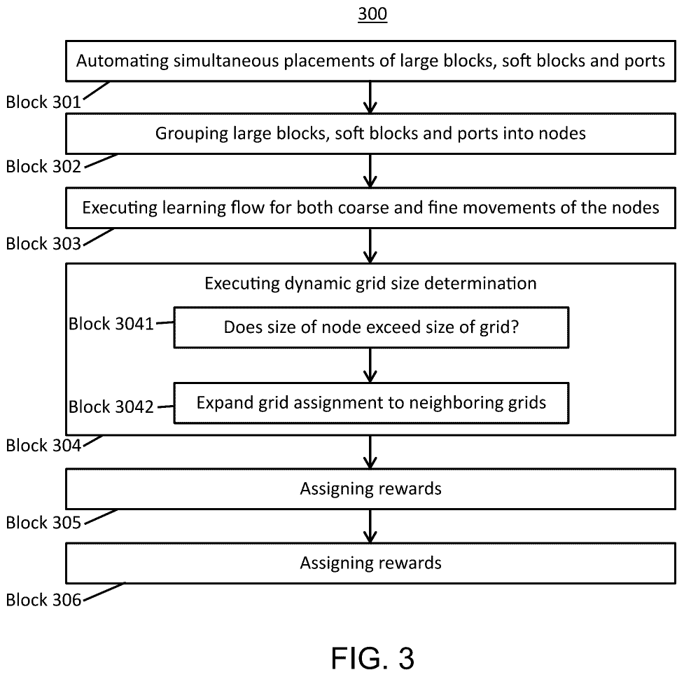

With reference to FIG. 3, a computer-implemented method 300 is provided for automated floorplan assistance. As shown in FIG. 3, the computer-implemented method 300 for automated floorplan assistance includes automating simultaneous placements of large blocks, soft blocks and ports into a grid using at least netlist definitions with connectivity information (block 301). The computer-implemented method 300 further includes grouping the large blocks, the soft blocks and the ports into nodes based on at least the connectivity information, user preferences and latch staging (block 302) and executing a learning flow for both coarse movements and fine movements of the nodes relative to the grid to iteratively improve a floorplan of the grid by assigning rewards associated with placement tool steering in accordance with learned attractions of the nodes toward certain areas of the grid (block 303). The executing of the learning flow of block 303 includes a learning phase for the coarse movements and a learning phase for the fine movements and where the coarse movements include assigning nodes to grids and the fine movements include moving nodes to neighboring grids. The rewards can be measured based on overall/local congestion, wirelengths, timing and power requirements. Higher rewards are associated with improved performance and no rewards or smaller rewards are associated with degraded performance. In addition, the computer-implemented method 300 includes executing a dynamic grid size determination based on sizes of the nodes to enable handling of multiple nodes of differing sizes together (block 304), assigning the rewards to the nodes by assigning a reward for each node at a given grid based on a weighted sum of global and local considerations with higher weights given to wirelengths and congestion (block 305) and generating an output comprising a grid size in accordance with the dynamic grid size determination and node assignments for each node at grid locations associated with greatest rewards (block 306). The dynamic grid size determination of block 304 can include determining whether a size of a node assigned to a grid exceeds a size of the grid (block 3041) and expanding the node assignment to the grid to a neighboring grid in an event the size of the node is determined to exceed the size of the grid (block 3042). The output can be used by a placement tool to physically place each large block, soft block and port of each node into a grid of a wafer or chip.

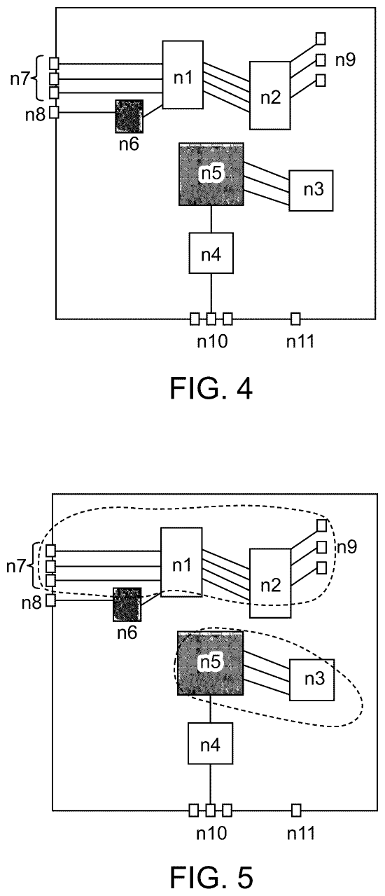

With reference to FIGS. 4-9, the computer-implemented method 300 of FIG. 3 will be described further.

As shown in FIGS. 4 and 5, a netlist includes hard blocks n1-n4, soft blocks n5 and n6 and ports n7-n11, each of the hard blocks n1-n4, soft blocks n5 and n6 and ports n7-n11 can be considered a node and the nodes are grouped based on at least connectivity information that is descriptive of connectivity percentages between nodes, user preferences and latch staging between nodes. This enables fast processing and an ability to explore similarities of structures. By representing nodes in groups a location of a group can be used as a median location, a node with maximal connectivity can be used as a connective median and/or a size of the biggest node can be used as a size median.

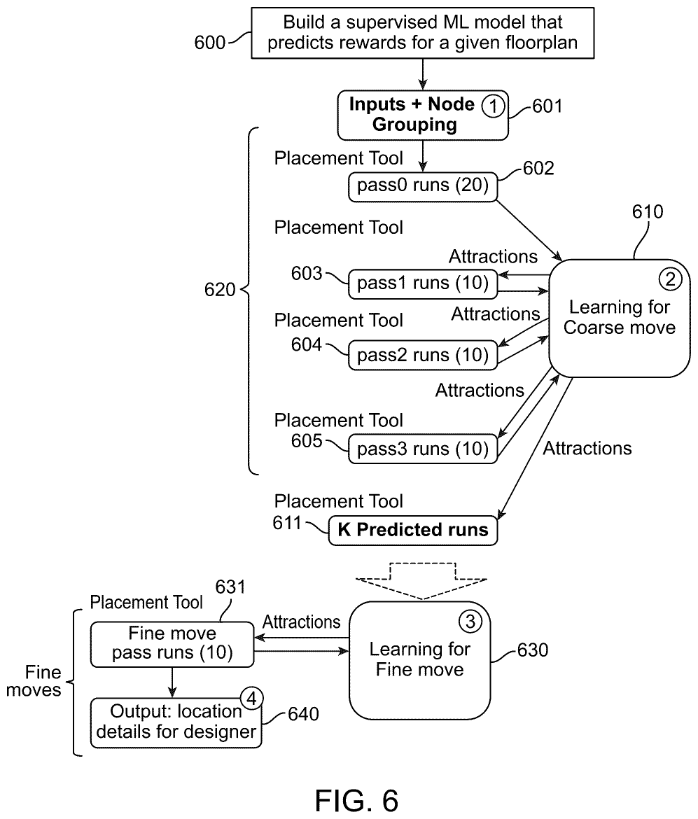

With reference to FIG. 6, the learning flow for coarse movements begin with reception of inputs and node groupings at block 601. At block 602, there is an initial random placement of nodes in grids and multiple such floorplan runs are taken through synthesis. The rewards from these floorplan runs are used for starting the learning for coarse moves. The ML model is subsequently re-trained using synthesis data from different floorplan runs made during coarse movement stages to be described below. Fine movement starts with building a supervised machine learning model using synthesis data generated with various floorplans explored in the coarse movement stage at block 629. Fine movement stages then use the trained ML model to predict overall/local rewards associated for example with moving nodes to neighboring grids. Thus, multiple fine moves can be evaluated without the overhead of running a synthesis tool as the ML model predicts the rewards to update a table to be described below.

That is, as shown in FIG. 6, reception of inputs and node groupings are executed at block 601. At blocks 602-605, placement tool runs are modeled for various coarse movements of the nodes. At the end of each run, an ML unit 610 of the ML model provided for coarse movement learning receives data reflective of the run and determines what is successful and what is not successful. From this information, the ML unit 610 generates attractions that are used to encourage coarse movements of the nodes toward positions where improved performance can be expected during subsequent runs of each of the various coarse movements of the nodes. At block 611, following a predicted number of runs, a supervised machine learning model using synthesis data generated with various floorplans explored in the coarse movement stage in built at block 629. This model is input to an ML unit 630 of the ML model that is provided for fine movement learning. The ML unit 630 generates attractions that are used to encourage fine movements of the nodes toward positions where improved performance can be expected during subsequent runs. At block 631, placement tool runs are made using attractions towards best rewarded grids from the updated table to be described below. At block 640, an output is generated, with the output being reflective of what is learned by ML units 610 and 630.

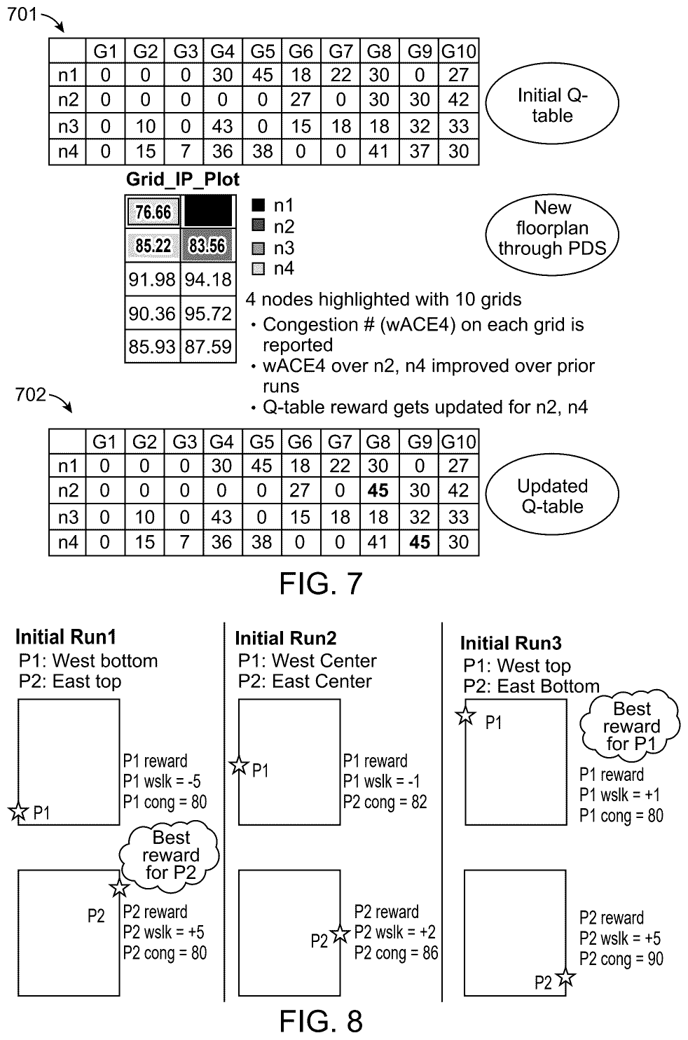

With reference to FIG. 7, it is to be understood that an objective of the learning flow for both the coarse movements and the fine movements of the nodes is to predict an optimal location in which nodes are to be placed in a grid. This is achieved by building an initial table 701 that defines grid assignments for each node in a netlist. From this initial table 701, it can be determined whether one or more of the nodes should have its node assignment changed due to one or more reasons (i.e., to ease congestion, to improve wirelengths, to improve timing, to reduce power requirements, etc.) that are determined during the learning flow. This can be achieved by defining a reward to be assigned to the node at the new grid location and which can be effectively interpreted as an instruction to change the node assignment for that node. This changed node assignment is reflected in the updated table 702. The locations giving good rewards are then predicted for future runs.

With reference to FIG. 8, a graphical explanation of the coarse movement learning flow and the rewards is illustrated. As shown in FIG. 8, the optimal location of port P1 is determined to be the location of port P1 in initial run3 whereas the optimal location of port P2 is determined to be the location of port P2 in initial run1. As such, the reward defined for port P1 is associated with the location of port P1 in initial run3 and would be reflected in the updated table 702 of FIG. 7 and the reward defined for port P2 is associated with the location of port P2 in initial run1 and would be reflected in the updated table 702 of FIG. 7.

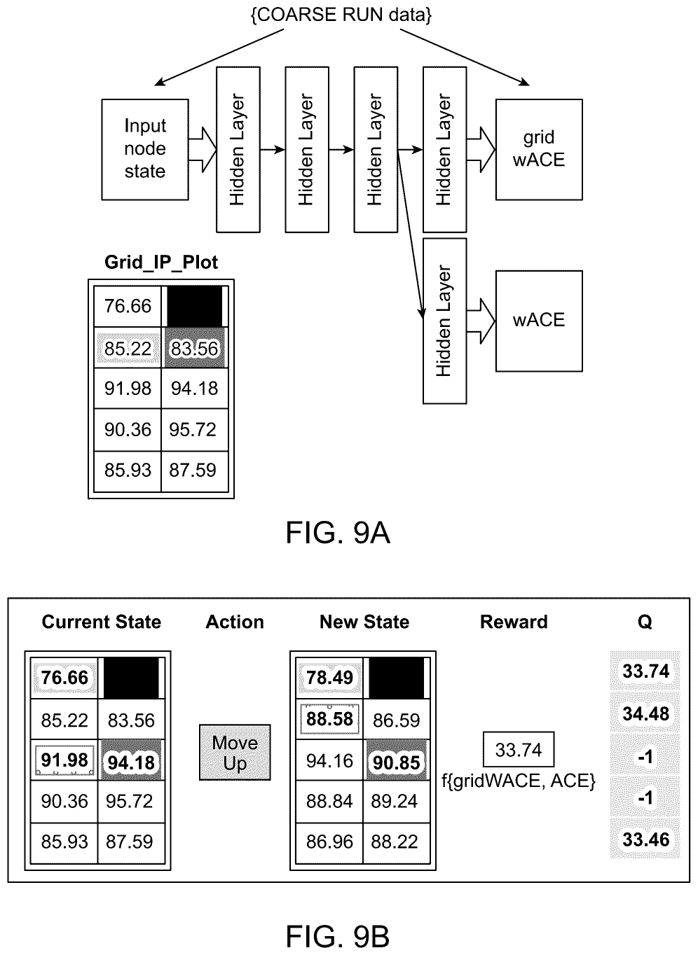

With reference to FIG. 9A, an operation of the ML model is illustrated. As shown in FIG. 9A, the ML model predicts rewards for a given floorplan as a preprocess for subsequent fine movements and the ML model is trained using synthesis runs generated with different floorplans from the coarse movement stages.

With reference to FIG. 9B, a graphical explanation of the fine movement learning flow and the rewards is illustrated. As used herein, fine movements of the nodes can be defined as those movements whereby, once the nodes are coarsely placed into a grid, it is determined whether they should be moved slightly (i.e., to neighboring grids) in order to improve performance further. As shown in FIG. 9B, an optimal location of a node in a grid is determined by evaluating fine movements of the node away from its coarse placement location. As above, a reward is defined for those fine movements which lead to improved performance and would be reflected in the updated table 702 of FIG. 7.

Regarding the dynamic grid size determination of block 304 of FIG. 3, a grid size can be defined based on sizes of nodes, where a given large block size may be defined in an IP abstract for the large block size and a soft block size can be computed as sum of sizes of all logic gates in the soft block with an aspect ratio of 1:1 unless passed. As used herein, “dynamic grid size” can be defined as mean of node sizes with an aspect ratio of 1:1. If a node size is greater than a grid size, then a node assignment to that grid expands to one or more neighboring grids during the executing of the learning flow. Masking can be used to prevent assignments of other nodes to neighboring grids in a case of overflow. In addition, user defined user masking can be employed if certain grids are not legal for node placement.

Regarding the rewards, a reward can be assigned to each node based on at least two factors. These include, but are not limited to, global considerations and local considerations. A global reward is a measure of overall congestion, timing, wirelength, power requirements, etc. A local reward is a measure for each node based on local characteristics. Reward for each node at a given grid location can be a weighted sum of a global reward and a local reward with higher weights given to wirelength and congestion considerations. For local rewards for a large block, LR (lcong)=use congestion on tiles above and immediate neighbor tiles of block; LR (ltiming)=sum of failing slack on all pins of large block; LR (lpower)=sum of power consumed by nets connected to pins of large block. For local rewards for a soft block, LR (scong)=use congestion on tiles above and immediate neighbor tiles of block; LR (stiming)=sum of failing slack of latches inside the soft block; LR (spower)=sum of power consumed by all gates in soft block. For local rewards for ports, LR (pcong)=use congestion on tiles around port location; LR (ptiming)=failing slack on the port; LR (ppower)=0.

A final output can include the following information: for a large block, placement information in a grid, for a soft block, a bounding box within which the soft block instances can be placed and, for ports, a pin file with locations in the grid for port placement.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer-implemented method for automated floorplan assistance, the computer-implemented method comprising:
automating simultaneous placements of large blocks, soft blocks and ports into a grid;
grouping the large blocks, the soft blocks and the ports into nodes;
executing a learning flow for both coarse movements and fine movements of the nodes relative to the grid to iteratively improve a floorplan of the grid by assigning rewards associated with placement tool steering in accordance with learned attractions of the nodes toward certain areas of the grid;
executing a dynamic grid size determination based on sizes of the nodes to enable handling of multiple nodes of differing sizes together; and
generating an output comprising a grid size in accordance with the dynamic grid size determination and node assignments for each node at grid locations associated with greatest rewards.

2. The computer-implemented method according to claim 1, wherein the automating of the simultaneous placements comprises netlist definitions with connectivity information.

3. The computer-implemented method according to claim 1, wherein the grouping of the large blocks, the soft blocks and the ports into the nodes is based on at least connectivity information and user preferences.

4. The computer-implemented method according to claim 1, wherein:
the executing of the learning flow comprises a learning phase for the coarse movements and a learning phase for the fine movements, and
the coarse movements comprise assigning nodes to grids and the fine movements comprise moving nodes to neighboring grids.

5. The computer-implemented method according to claim 1, wherein the rewards are based on overall/local congestion, wirelengths, timing and power requirements.

6. The computer-implemented method according to claim 1, wherein the dynamic grid size determination comprises expanding a node assignment to a grid to a neighboring grid in an event a size of the node exceeds a size of the grid.

7. The computer-implemented method according to claim 1, further comprising assigning a reward for each node at a given grid based on a weighted sum of global and local considerations with higher weights given to wirelengths and congestion.

8. A computer program product for automated floorplan assistance, the computer program product comprising one or more computer readable storage media having computer readable program code collectively stored on the one or more computer readable storage media, the computer readable program code being executed by a processor of a computer system to cause the computer system to perform a method comprising:
automating simultaneous placements of large blocks, soft blocks and ports into a grid;
grouping the large blocks, the soft blocks and the ports into nodes;
executing a learning flow for both coarse movements and fine movements of the nodes relative to the grid to iteratively improve a floorplan of the grid by assigning rewards associated with placement tool steering in accordance with learned attractions of the nodes toward certain areas of the grid;
executing a dynamic grid size determination based on sizes of the nodes to enable handling of multiple nodes of differing sizes together; and
generating an output comprising a grid size in accordance with the dynamic grid size determination and node assignments for each node at grid locations associated with greatest rewards.

9. The computer program product according to claim 8, wherein the automating of the simultaneous placements comprises netlist definitions with connectivity information.

10. The computer program product according to claim 8, wherein the grouping of the large blocks, the soft blocks and the ports into the nodes is based on at least connectivity information and user preferences.

11. The computer program product according to claim 8, wherein:
the executing of the learning flow comprises a learning phase for the coarse movements and a learning phase for the fine movements, and
the coarse movements comprise assigning nodes to grids and the fine movements comprise moving nodes to neighboring grids.

12. The computer program product according to claim 8, wherein the rewards are based on overall/local congestion, wirelengths, timing and power requirements.

13. The computer program product according to claim 8, wherein the dynamic grid size determination comprises expanding a node assignment to a grid to a neighboring grid in an event a size of the node exceeds a size of the grid.

14. The computer program product according to claim 8, wherein the method further comprises assigning a reward for each node at a given grid based on a weighted sum of global and local considerations with higher weights given to wirelengths and congestion.

15. A computing system comprising:
a processor;
a memory coupled to the processor; and
one or more computer readable storage media coupled to the processor, the one or more computer readable storage media collectively containing instructions that are executed by the processor via the memory to implement a method for automated floorplan assistance comprising:
automating simultaneous placements of large blocks, soft blocks and ports into a grid;
grouping the large blocks, the soft blocks and the ports into nodes;
executing a learning flow for both coarse movements and fine movements of the nodes relative to the grid to iteratively improve a floorplan of the grid by assigning rewards associated with placement tool steering in accordance with learned attractions of the nodes toward certain areas of the grid;
executing a dynamic grid size determination based on sizes of the nodes to enable handling of multiple nodes of differing sizes together; and
generating an output comprising a grid size in accordance with the dynamic grid size determination and node assignments for each node at grid locations associated with greatest rewards.

16. The computing system according to claim 15, wherein the grouping of the large blocks, the soft blocks and the ports into the nodes is based on at least connectivity information and user preferences.

17. The computing system according to claim 15, wherein:
the executing of the learning flow comprises a learning phase for the coarse movements and a learning phase for the fine movements, and
the coarse movements comprise assigning nodes to grids and the fine movements comprise moving nodes to neighboring grids.

18. The computing system according to claim 15, wherein the rewards are based on overall/local congestion, wirelengths, timing and power requirements.

19. The computing system according to claim 15, wherein the dynamic grid size determination comprises expanding a node assignment to a grid to a neighboring grid in an event a size of the node exceeds a size of the grid.

20. The computing system according to claim 15, wherein the method for automated floorplan assistance further comprises assigning a reward for each node at a given grid based on a weighted sum of global and local considerations with higher weights given to wirelengths and congestion.
